(19) United States
(12) Patent Application Publication
(10) Pub. No.: US 2016/0268296 A1
(43) Pub. Date: Sep. 15, 2016

(54) SEMICONDUCTOR MEMORY DEVICE AND METHOD FOR MANUFACTURING SAME

(71) Applicant: KABUSHIKI KAISHA TOSHIBA, Minato-ku (JP)

(72) Inventor: Tsuneo UENAKA, Yokkaichi (JP)

(73) Assignee: KABUSHIKI KAISHA TOSHIBA, Minato-ku (JP)

(21) Appl. No.: 14/833,200

(22) Filed: Aug. 24, 2015

Related U.S. Application Data
(60) Provisional application No. 62/133,119, filed on Mar. 13, 2015.

(51) Int. Cl. H01L 27/115; H01L 23/528; H01L 21/768; H01L 21/28; H01L 21/02; H01L 29/423; H01L 23/532

(52) U.S. Cl. CPC H01L 27/11582; H01L 27/11568; H01L 29/42344; H01L 23/528; H01L 23/53295; H01L 21/28282; H01L 21/02164; H01L 21/0217; H01L 21/76802; H01L 21/76831; H01L 21/76877

(57) ABSTRACT

According to one embodiment, a semiconductor memory device includes a stacked body including a plurality of electrode layers; a select gate; a first insulating layer; a semiconductor portion including a top end portion; a charge storage film; a second insulating layer provided on the stacked body; a third insulating layer; and a contact portion. The third insulating layer includes: a first portion provided on the select gate with the first insulating layer between the first portion and the select gate, the first portion being in contact with an upper surface of the first insulating layer and separated from the second insulating layer, and a second portion provided on the second insulating layer, the second portion being in contact with the second insulating layer and separated from the first insulating layer, a thickness of the second portion being thicker than a thickness of the first portion in the stacking direction.

This application is based upon and claims the benefit of priority from U.S. Provisional Patent Application 62/133,119 field on Mar. 13, 2015; the entire contents of which are incorporated herein by reference.

### FIELD

Embodiments described herein relate generally to a semiconductor memory device and a method for manufacturing same.

### BACKGROUND

Memory devices having a three-dimensional structure in which electrode layers function as control gates in each memory cell have been proposed. In these memory devices, a plurality of electrode layers is formed separated by insulating layers. Memory holes are formed in the resulting stacked body, and silicon bodies that serve as channels are provided along the sidewalls of the memory holes with charge storage films disposed therebetween.

Reactive ion etching (RIE), for example, is used to form the memory holes and the contacts connected to the memory holes in the stacked bodies of such three-dimensional devices. Manufacturing such three-dimensional devices becomes increasingly difficult as the devices become smaller.

### BRIEF DESCRIPTION OF THE DRAWINGS

FIG. 1 is a schematic perspective view of a memory cell array of an embodiment;

FIGS. 2A and 2B are schematic cross-sectional views a part of the memory strings of the embodiment;

FIG. 3A is an enlarged schematic cross-sectional view a part of the column of the embodiment and FIG. 3B is schematic cross-sectional view a part of the memory strings of the embodiment;

FIG. 4A to FIG. 7B are schematic cross-sectional views showing a method for manufacturing the semiconductor memory device of the embodiment;

FIGS. 8A and 8B are schematic plan views a layout of the memory strings of the embodiment;

FIG. 9 is a schematic cross-sectional view of the layout of the memory strings of the embodiment; and

FIG. 10 is a schematic perspective view of a memory cell array of another embodiment.

### DETAILED DESCRIPTION

According to one embodiment, a semiconductor memory device includes a stacked body including a plurality of electrode layers separately stacked each other; a select gate provided on the stacked body; a first insulating layer provided on the select gate; a semiconductor portion provided in the stacked body and the select gate, the semiconductor portion extending in a stacking direction of the stacked body, the semiconductor portion including a top end portion positioned on the select gate; a charge storage film provided between the semiconductor portion and the plurality of electrode layers; a second insulating layer provided on the stacked body and extending in the stacking direction and in a first direction crossing the stacking direction, the second insulating layer being in contact with a side surface of the select gate and a side surface of the first insulating layer; a third insulating layer continuously provided on the second insulating layer and the select gate; and a contact portion connected to the top end portion of the semiconductor portion, the contact portion extending in the stacking direction. The third insulating layer includes: a first portion provided on the select gate with the first insulating layer between the first portion and the select gate, the first portion being in contact with an upper surface of the first insulating layer and separated from the second insulating layer, and a second portion provided on the second insulating layer, the second portion being in contact with the second insulating layer and separated from the first insulating layer, a thickness of the second portion being thicker than a thickness of the first portion in the stacking direction.

Embodiments will be described below with reference to drawings. Note that the same reference numerals are applied for the same elements in each drawing.

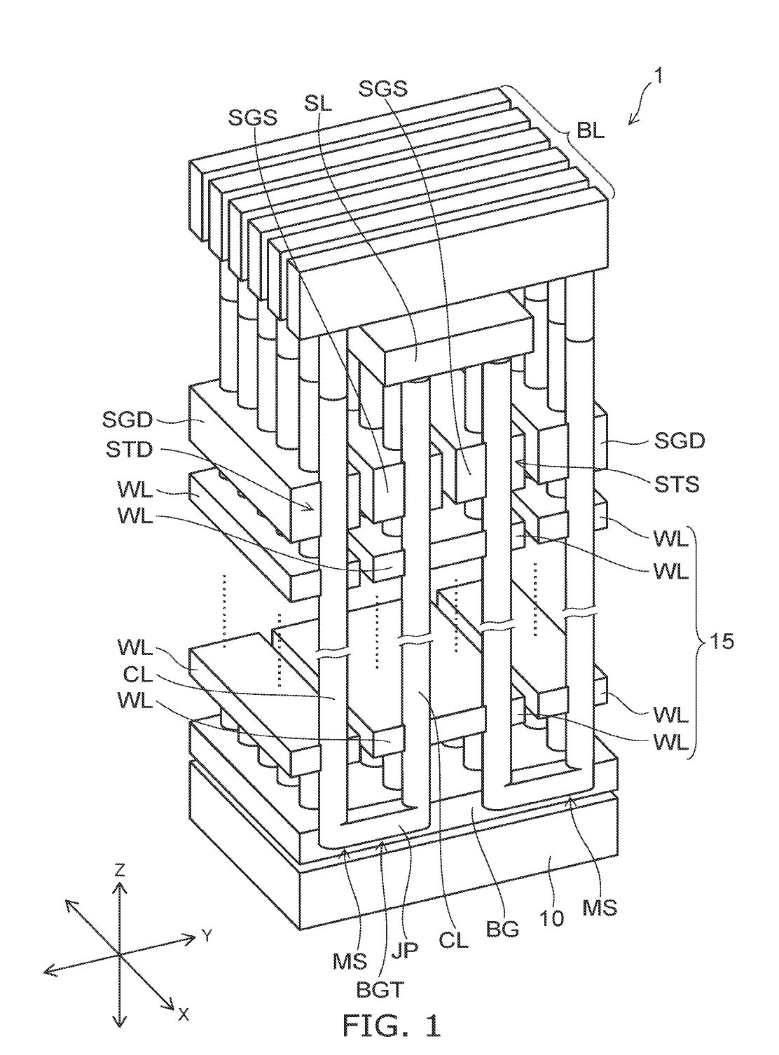

FIG. 1 is a perspective view schematically illustrating a memory cell array 1 according to an embodiment. For simplicity, elements such as the insulating layers and insulating films between electrodes are not illustrated in FIG. 1.

FIG. 1 includes a coordinate system in which two mutually orthogonal directions are the X direction and the Y direction. Moreover, the direction in which a plurality of electrode layers WL are stacked (the stacking direction) is the Z direction. The Z direction is orthogonal to both the X direction and the Y direction (that is, to the XY plane).

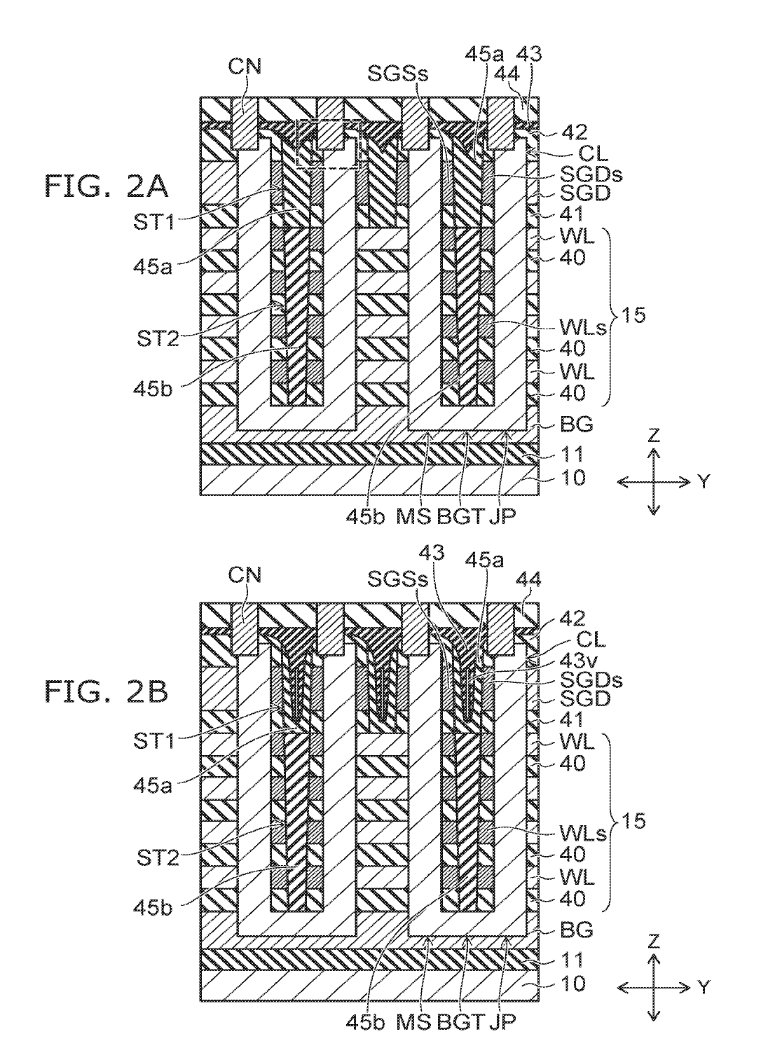

The memory cell array 1 includes a plurality of memory strings MS. FIG. 2A is a cross-sectional view schematically illustrating a portion of the memory strings MS of the embodiment. The cross section illustrated in FIG. 2A runs parallel to the YZ plane in FIG. 1.

The memory cell array 1 includes a stacked body 15. The stacked body 15 includes a plurality of electrode layers WL and a plurality of insulating layer 40. The plurality of electrode layers WL is separately stacked each other, and the plurality of insulating layers 40 is provided between the plurality of electrode layers WL. The electrode layers WL and insulating layers 40 are stacked alternately, for example. The stacked body 15 is provided on a back gate BG that serves as a lower gate layer. The number of the electrode layers WL illustrated in the drawings is an example, and the number of the electrode layers WL may be arbitrary. The back gate BG is provided on a substrate 10 with an insulating layer 11 disposed therebetween.

A single memory string MS is formed in a U-shape and includes a pair of columns CL extending in the Z direction, and a connecting portion JP that connects the respective bottom ends of the pair of columns CL. The columns CL are cylinder-shaped or elliptic cylinder-shaped and extend through the stacked body 15 into the back gate BG. The connecting portion JP only has to connect at least the bottom ends of adjacent columns CL in each pair of columns CL. For example, the connecting portion JP may connect the bottom ends of not less than two columns CL, for example.

A drain side select gate SGD is provided on a top end of one of the pair of columns CL in the U-shaped memory string MS, and a source side select gate SGS is provided on a top end of the other. The drain side select gate SGD and the source side select gate SGS are provided on the topmost layer of the electrode layers WL with an insulating layer 41 disposed therebetween. In the following description, the drain side select gates SGD and the source side select gate SGS are sometimes referred to simply as select gates SG.

The back gate BG, electrode layers WL, and select gates SG are layers made primarily from a silicon material, such as polycrystalline silicon layers. The silicon layers that form the back gate BG, the electrode layers WL, and the select gates SG contain boron impurities, for example, to make the layers conductive. The back gate BG, the electrode layers WL, and the select gates SG may also contain a metal or a metal silicide. The insulating layers 40 are made primarily from silicon oxide, for example. The insulating layers 40 may include air gaps (cavities), for example.

The select gate SG that serve as an upper select gate and the back gate BG that serves as a lower select gate are thicker than a single electrode layer WL, for example. Moreover, a plurality of these gates is provided, for example. Note that the thicknesses of the select gate SG and the back gate BG may be less than or equal to the thickness of a single electrode layer WL. Here, the term “thickness” refers to thickness in the stacking direction of the stacked body 15 (that is, in the Z direction).

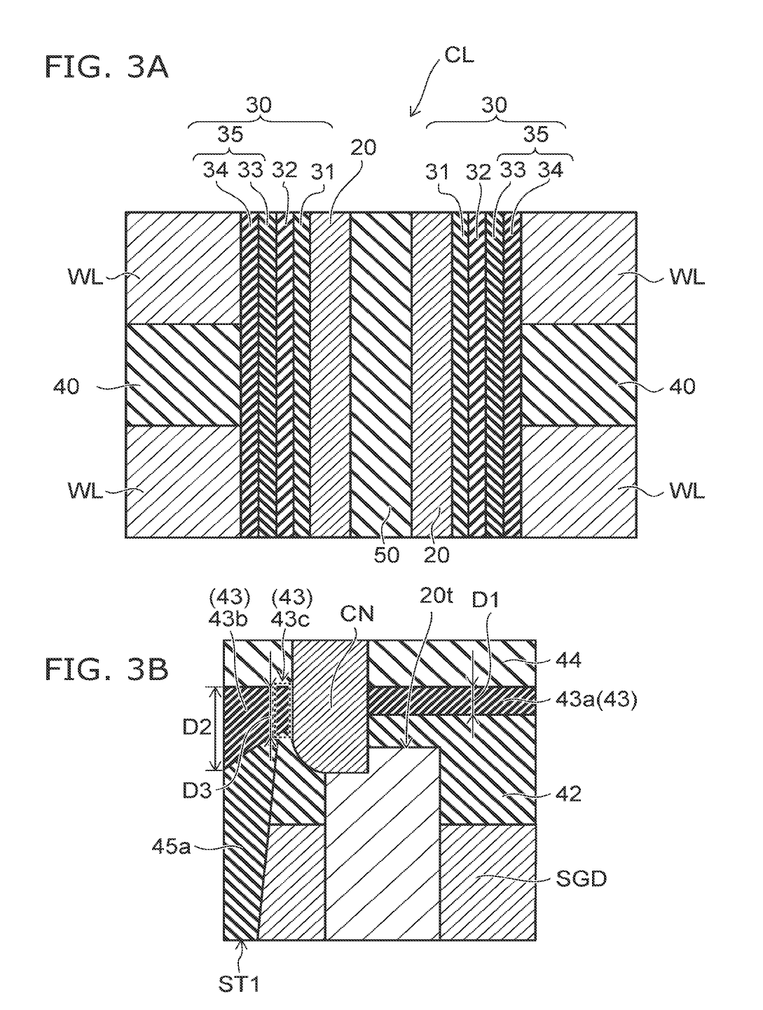

As illustrated in FIGS. 2A and 3B, an insulating separator ST1 is provided on the stacked body 15, and extends in the X direction. The insulating separator ST1 includes an insulating layer 45a (a second insulating layer) extending in the X direction. The insulating film 45a is in contact with a side surface of the select gates SG and a side surface of the insulating layer 42 (first insulating layer). The select gates SG are separated in the Y direction with the insulating separator ST1 between each of select gates SG. The insulating separator ST1 is provided between the pair of columns CL, the pair of columns CL is provided in the select gates SG, for example. The insulating separator ST1 is separated from the pair of columns CL with the select gates SG between the insulating separator ST1 and the pair of columns CL, and with the insulating layer 42 between the insulating separator ST1 and the pair of columns CL. The pair of columns CL are integrally provided via the connecting portion JP. An insulating separator ST2 (an insulating portion) is provided in the stacked body 15 and extends in the X direction. The insulating separator ST2 includes an insulating layer 45b extending in the X direction. The stacked body 15 is divided in the Y direction by the insulating separator ST2. In the stacked body 15, the pair of columns CL is divided in the Y direction by the insulating separator ST2.

In the example illustrated in FIG. 2A, the insulating separators ST1 and ST2 are provided between the pair of columns CL, the insulating separators ST1 and ST2 are integrally connected in the Z direction (that is, in the stacking direction). Meanwhile, on the outer sides of each pair of columns CL, only an insulating separator ST1 is provided, for example.

As illustrated in FIG. 1, a source layer SL (a metal film, for example) is provided on the source side select gates SGS and separated therefrom by insulating layers 42, 43, and 44. As illustrated in FIG. 1, a plurality of bit lines BL (metal films, for example) is provided on the drain side select gates SGD and the source layer SL. The bit lines BL extend in the Y direction. The source layer SL and the bit lines BL are electrically connected to the columns CL via contact portions CN.

FIG. 3A is an enlarged cross-sectional view schematically illustrating a portion of the column CL of the embodiment.

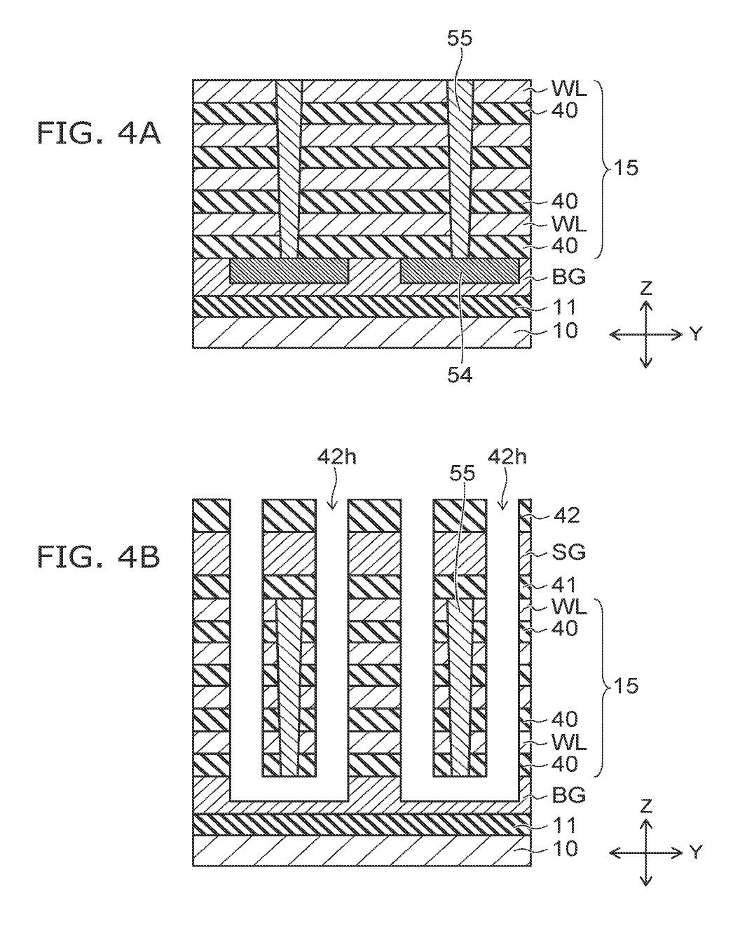

The columns CL are provided in U-shaped memory holes 42h (see FIG. 4B), the memory holes 42h is provided in the stacked body 15, the select gate SG and the back gate BG. A channel body 20 (a semiconductor portion) is provided in each memory holes 42h, and functions as a semiconductor channel. The channel body 20 is, for example, a silicon film. The impurity concentration of the channel body 20 is lower than the impurity concentration of the electrode layer WL.

A memory film 30 is provided between the inner wall of the memory hole 42h and each channel body 20. The memory film 30 includes a block insulating film 35, a charge storage film 32, and a tunnel insulating film 31.

The block insulating film 35, the charge storage film 32, and the tunnel insulating film 31 are provided, in order from the electrode layer WL side, between the electrode layers WL and the channel body 20.

The channel body 20 has a hollow cylindrical shape and extends in the stacking direction of the stacked body 15. The memory film 30 is also provided in a hollow cylindrical shape, the memory film 30 extends in the stacking direction of the stacked body 15 and surrounds the outer peripheral surface of the channel body 20. The electrode layer WL surrounds the periphery of the channel body 20 via the memory film 30. Moreover, a core insulating film 50 is provided inside the channel body 20, for example. The core insulating film 50 is a silicon oxide film, for example. The channel body 20 may have a cylindrical shape that does not include a core insulating film 50 provided therein, for example. As illustrated in FIG. 3B, a top end 20t of the channel body 20 is connected to the contact portion CN.

The block insulating film 35 is in contact with the electrode layers WL, and the tunnel insulating film 31 is in contact with the channel body 20. The charge storage film 32 is provided between the block insulating film 35 and the tunnel insulating film 31.

The channel body 20 functions as the channel of the memory cell, and the electrode layers WL function as control gates of the memory cell. The charge storage film 32 functions as a data memory layer that stores electric charge injected from the channel body 20. In other words, the memory cell is provided in a configuration in which a control gate surrounds the channel periphery at the location where the channel body 20 and each electrode layer WL intersect.

The semiconductor memory device of the embodiment is a non-volatile semiconductor memory device that can freely erase and write data electrically, and can retain the contents of the memory even when the power supply is turned off.

The memory cell is, for example, a charge trap type of memory cell. The charge storage film 32 has a large number of trapping sites for trapping electric charge and is a silicon nitride film, for example.

The tunnel insulating film 31 serves as a potential barrier when electric charge is injected into the charge storage film 32 from the channel body 20. The tunnel insulating film 31 is a silicon oxide film, for example.

Alternatively, a stacked film (ONO film) in which a silicon nitride film is interposed between a pair of silicon oxide films may be used for the tunnel insulating film 31. When the ONO film is used for the tunnel insulating film 31, the erasing operation can be performed in a weaker electric field than when a single-layer silicon oxide film is used.

The block insulating film 35 prevents electric charge stored in the charge storage film 32 from diffusing into the electrode layers WL. The block insulating film 35 includes a cap film 34 and a block film 33, for example. The cap film 34 is provided in contact with the electrode layers WL. The block film 33 is provided between the cap film 34 and the charge storage film 32.

The block film 33 is a silicon oxide film, for example. The cap film 34 has a higher permittivity than silicon oxide and is a silicon nitride film, for example. Forming this cap film 34 in contact with the electrode layers WL can suppress back-tunneling of electrons injected from the electrode layers WL during erasing. In other words, using a stacked film that includes a silicon oxide film and a silicon nitride film for the block insulating film 35 enhances the electric charge blocking effect of the block insulating film 35.

As illustrated in FIG. 1, a drain side select transistor STD is provided on a top end of one column CL of the pair of columns CL of each U-shaped memory string MS, and a source side select transistor STS is provided on a top end of the other column CL.

The memory cell, drain side select transistor STD, and source side select transistor STS are vertical transistors in which current flows in the stacking direction of the stacked body 15 (that is, in the Z direction).

The drain side select gate SGD functions as a gate electrode (control gate) for the drain side select transistor STD. An insulating film that functions as a gate insulating film for the drain side select transistor STD is provided between the drain side select gate SGD and the channel body 20. The channel body 20 of the drain side select transistor STD is connected to one of the bit lines BL via the contact portion CN above the drain side select gate SGD.

The source side select gate SGS functions as a gate electrode (control gate) for the source side select transistor STS. An insulating film that functions as a gate insulating film for the source side select transistor STS is provided between the source side select gate SGS and the channel body 20. The channel body 20 of the source side select transistor STS is connected to the source layer SL via the contact portion CN above the source side select gate SGS.

A back gate transistor BGT is provided on the connecting portion JP of the memory string MS. The back gate BG functions as a gate electrode (control gate) for the back gate transistor BGT. The memory film 30 provided in the back gate BG functions as a gate insulating film of the back gate transistor BGT.

A plurality of memory cells is provided between the drain side select transistor STD and the back gate transistor BGT with the electrode layer WL of each layer as the control gate. Likewise, a plurality of memory cells is provided between the back gate transistor BGT and the source side select transistor STS with the electrode layer WL of each layer as the control gate.

The plurality of memory cells, the drain side select transistor STD, the back gate transistor BGT, and the source side select transistor STS are serially connected through the channel body 20 and form a single U-shaped memory string MS. This memory string MS is arrayed in plurality in the X direction and the Y direction, and therefore, a plurality of memory cells is three dimensionally provided in the X direction, Y direction, and Z direction.

Next, the configurations of the upper portions of the select gates SG of this embodiment will be described with reference to FIG. 2A.

As illustrated in FIG. 2A, a stopper layer 43 (a third insulating layer) is provided on the select gate SG with the insulating layer 42 disposed therebetween and on the insulating layer 45a. The stopper layer 43 includes a first portion 43a, a second portion 43b, and a third portion 43c.

The first portion 43a is provided on the select gate SG with the insulating layer 42 between the first portion 43a and the select gate SG, and on the channel body 20 with the insulating layer 42 between the first portion 43a and the channel body 20. The first portion 43a is in contact with the upper surface of the insulating layer 42 and separated from the insulating layer 45a. The second portion 43b is provided on the insulating layer 45a. The second portion 43b is in contact with the upper surface of the insulating layer 45a and separated from the insulating layer 42. The third portion 43c is provided between the first portion 43a and the second portion 43b. The third portion 43c may be provided between the contact portion CN and the second portion 43b. The third portion 43c is in contact with at least one of the insulating layer 42 and the insulating layer 45a. As viewed in the Z-direction, the third portion 43c overlaps with the select gates SG.

The thickness D2 of the second portion 43b is thicker than the thickness D1 of the first portion 43a. The thickness D3 of the third portion 43c is thicker than the thickness D1 of the first portion 43a and thinner than the thickness D2 of the second portion 43b. In other words, the stopper layer 43 becomes thicker as the stopper layer 43 separates away from the column CL. Here, the term “thickness” refers to thickness in the stacking direction of the stacked body 15 (that is, in the Z direction).

The stopper layer 43 includes a material different from a material included the insulating layers 42 and 44, and an insulating layer 45a. For example, the stopper layer 43 includes a silicon nitride film, and the insulating layers 42 and 44 and the insulating layer 45a include silicon oxide films. Tetraethyl orthosilicate (TEOS) may also be used for the insulating layer 44, for example.

In the manufacturing method described below, the stopper layer 43 is used as a stopper film while forming the contact portions CN.

At this time, as described above, the stopper layer 43 is provided such that the thickness of the stopper layer 43 becomes thicker as the stopper layer 43 separates away from the column CL according to this embodiment. This makes it possible to suppress the occurrence of errors in the alignment of the contact portions CN relative to the columns CL when forming those contact portions CN. In other words, this makes it possible to reduce the difficulty associated with manufacturing three-dimensional devices on increasingly smaller scales.

As illustrated in FIG. 3B, for example, even if a portion of one of the holes for forming one of the contact portions CN is misaligned away from the column CL and closer to the select gate SG, the etching process proceeds more slowly in that misaligned portion due to the increasing thickness of the stopper layer 43. Therefore, the resulting contact portion CN is provided more shallowly as the contact portion CN separates away from the column CL. This makes it possible to suppress the contact portions CN from being in contact with conductive elements other than the columns CL (such as the select gates SG, for example). Here, “shallowly” refers to an arrangement in which the contact portions CN are located away from the columns CL in the Z direction. If the contact portions CN are misaligned relative to the columns CL, for example, this makes it more difficult for those contact portions CN to be in contact with the select gates SG and to thereby cause a short-circuit.

Next, an example of a configuration for the stopper layer 43 will be described with reference to FIG. 2B.

As illustrated in FIG. 2B, the stopper layer 43 is provided in the insulating separator ST1, for example. Here, the stopper layer 43 inside the insulating separator ST1 is interposed between the select gates SG with the insulating layer 45a between the select gates SG and the stopper layer 43.

The stopper layer 43 includes the cavity 43v formed in the insulating separator ST1, for example. The cavity 43v is provided in the stopper layer 43 and is interposed between the select gates SG with the insulating layer 45a the select gates SG and the cavity 43v.

The permittivity of the cavity 43v is lower than the permittivity of the insulating layer 45a and the stopper layer 43. This makes it possible to reduce parasitic capacitance, reduce leakage current, or improve breakdown voltage in the insulating separator ST1.

Furthermore, the thickness of the stopper layer 43 may be thicker as the stopper layer 43 separates away from the column CL. The location where the thickest portion of the stopper layer 43 is provided may be arbitrary.

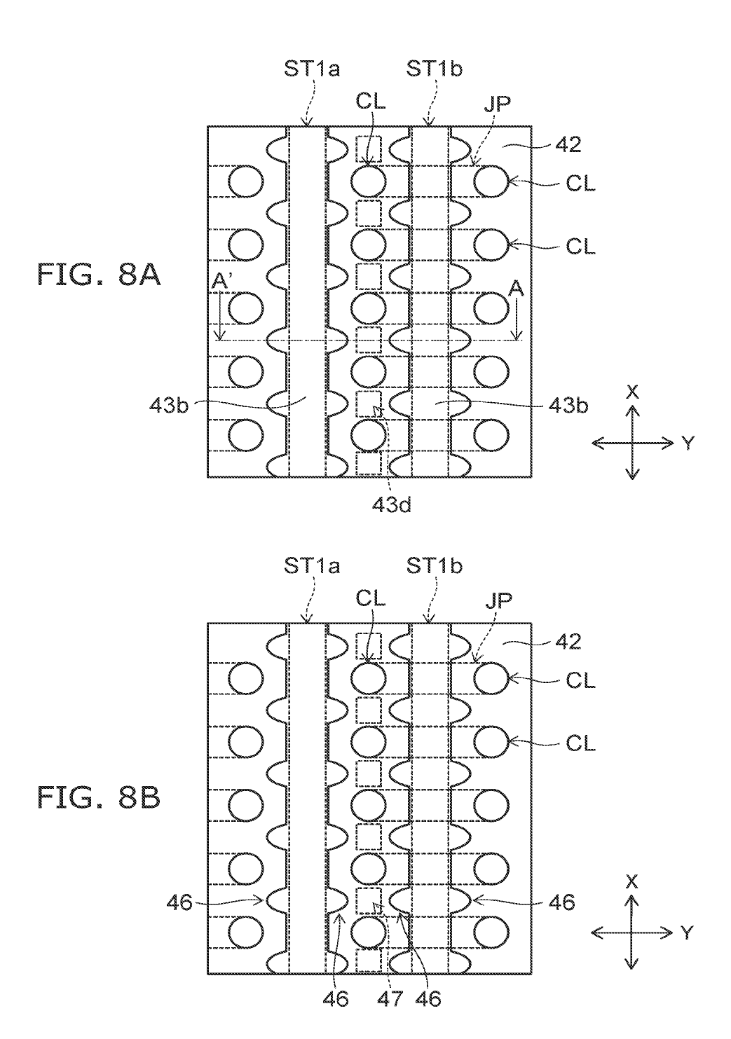

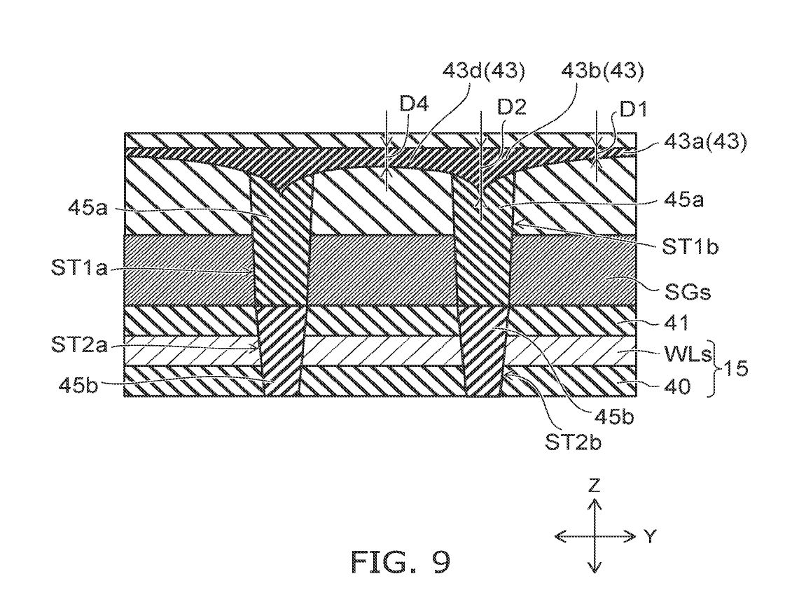

An example of a layout for this embodiment will be described with reference to FIG. 8A and FIG. 9.

FIG. 8A is a plan view schematically illustrating a layout of the memory string of the embodiment and illustrating the upper surface of the insulating layer 42. FIG. 9 is a schematic cross-sectional view corresponding to line A-A′ in FIG. 8A. In FIG. 9, the thickness D1 of the first portion 43a is equal to the thickness D1 of the first portion 43a in FIG. 3B, and the thickness D2 of the second portion 43b is equal to the thickness D2 of the second portion 43b in FIG. 3B.

As illustrated in FIG. 8A and FIG. 9, a plurality of pairs of columns CL each connected by a corresponding connecting portion JP are provided in the XY plane. A prescribed gap is left between the columns CL in both the X and Y directions. An insulating separator ST1a (a first insulating portion) and an insulating separator ST1b (a second insulating portion) extend in the X direction and interpose the columns CL. The second portions 43b of the stopper layer 43 are provided on the insulating separators ST1a and ST1b.

Fourth portions 43d of the stopper layer 43 are provided in the locations interposed between the insulating separators ST1a and ST1b. These fourth portions 43d are also interposed between the columns CL in the X direction. The thickness D4 of the fourth portions 43d is thicker than the thickness D1 of the first portions 43a and thinner than the thickness D2 of the second portions 43b.

As a result, the stopper layer 43 includes the second portions 43b and the fourth portions 43d, the second portions 43b and the fourth portions 43d are located at positions further from the columns CL, and thickness D2 of the second portions 43b and the thickness D4 of the fourth portions 43d are thicker than the thickness D1 the first portions 43a. This makes it possible to suppress the occurrence of errors in the alignment of the contact portions CN relative to the columns CL when forming those contact portions CN. In other words, this makes it possible to reduce the difficulty associated with manufacturing three-dimensional devices on increasingly smaller scales.

Next, a method for manufacturing the semiconductor memory device of the embodiment will be described with reference to FIGS. 4A to 7B.

As illustrated in FIG. 4A, the back gate BG is formed on the substrate 10 with the insulating layer 11 disposed therebetween. Sacrificial films 54 are formed in the back gate BG. The sacrificial films 54 are removed later when the connecting portions JP are formed.

The stacked body 15 is formed on the back gate BG and the sacrificial films 54, the stacked body 15 includes the electrode layers WL and the insulating layers 40. The electrode layers WL are separately stacked each other on the back gate BG, and the insulating layers 40 are formed between the electrode layers WL. The number of electrode layers WL and the number of insulating layers 40 are optional.

Then, trenches that extend in the stacking direction of the stacked body 15 and in a direction piercing through the paper surface are formed. The trenches are formed by reactive ion etching (RIE) using a mask (not illustrated), for example. The trenches extend down through the lowermost electrode layer WL of the stacked body 15 and reach the lowermost insulating layer 40. The bottom surfaces of the trenches are formed above the sacrificial films 54 in the back gate BG. Sacrificial films 55 are formed in the trenches.

As illustrated in FIG. 4B, the insulating layer 41 and the select gates SG are formed on the stacked body 15. The insulating layer 42 is formed on the select gates SG. The insulating layer 42 is a silicon oxide film, for example.

Next, the holes 42h are formed down through the insulating layer 42 and the stacked body 15 and reaching to the sacrificial films 54 of the back gate BG. A pair of holes 42h are formed on each sacrificial film 54. The holes 42h are formed by RIE using a mask (not illustrated), for example.

Then, the sacrificial films 54 are removed by etching through the holes 42h. The sacrificial films 54 are removed by wet etching, for example. In this way, the pair of holes 42h is integrally formed.

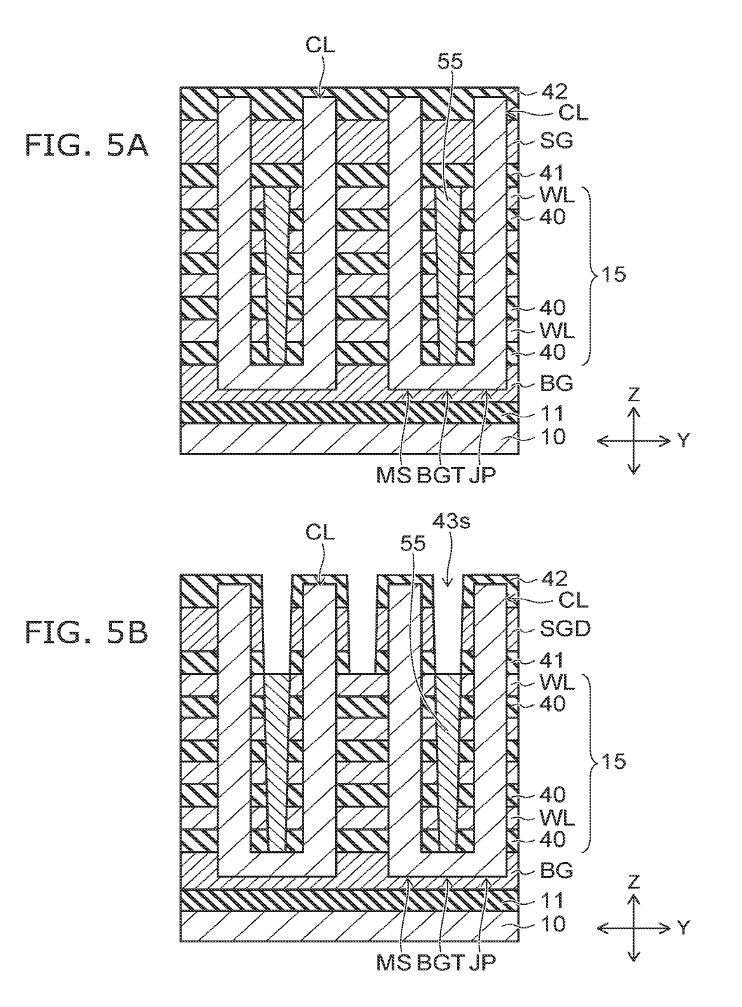

As illustrated in FIG. 5A, the films illustrated in FIG. 3A (including the memory film 30 and the channel body 20) are formed in order on the inner walls of the holes 42h (on the side surfaces and bottom surface). Then, the films formed on the insulating layer 42 are removed. Accordingly, the columns CL and the connecting portions JP connecting the columns CL are formed. Next, an insulating layer 42 is formed on the columns CL.

As illustrated in FIG. 5B, trenches 43s that go through the insulating layer 42 and extend in the stacking direction and in the direction piercing through the paper surface are formed. The trenches 43s are formed by RIE using a mask (not illustrated), for example.

The trenches 43s formed on the connecting portions JP go through the insulating layer 42 and the select gates SG and reach down to the sacrificial films 55. The trenches 43s formed in locations other than over the connecting portions JP go through the insulating layer 42 and the select gates SG and reach down to the stacked body 15. In this way, the trenches 43s divide the select gates SG into the source side select gates SGS and the drain side select gates SGD.

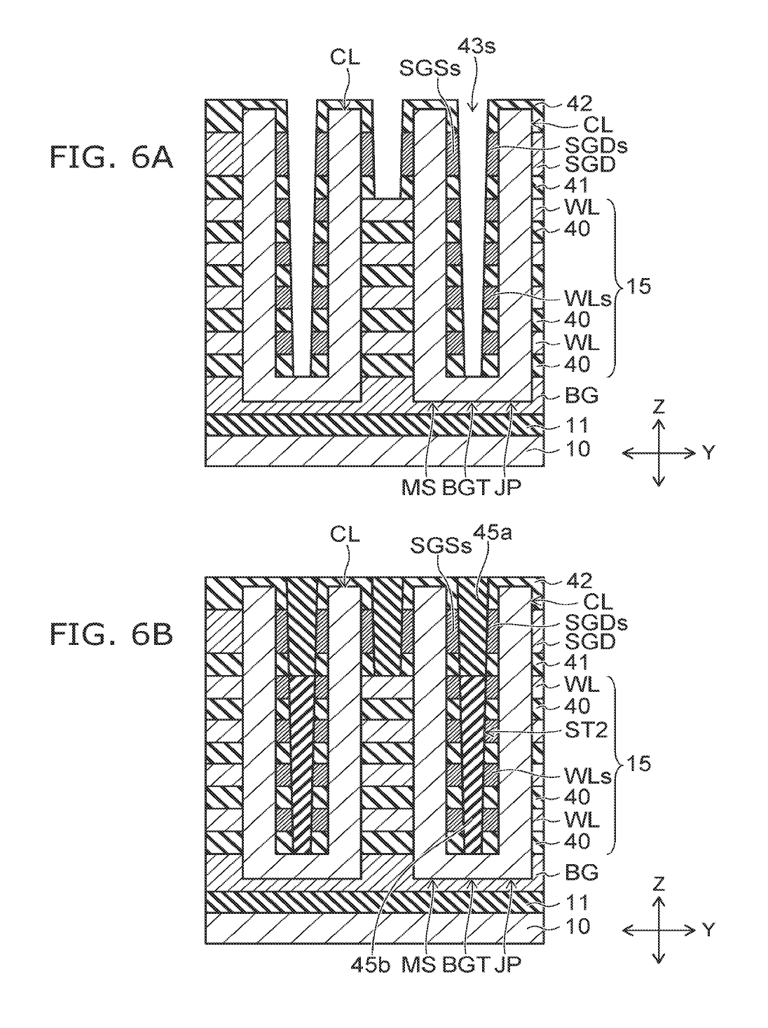

As illustrated in FIG. 6A, the sacrificial films 55 are removed through the trenches 43s. In this way, the trenches 43s formed on the connecting portions JP are formed all the way from the insulating layer 42 to the bottom layer of the stacked body 15.

Next, a metal silicide process on the silicon layers may be performed through the trenches 43s, for example. In this process, metal silicide portions (WLs, SGDs, and SGSs) are formed on the electrode layers WL and the select gates SG, thereby reducing the resistance.

In the metal silicide process, metal films are formed conforming to the sidewalls of the trenches 43s and annealed at a high temperature, for example. This causes the silicon contained in the electrode layers WL and the select gates SG to react with the metal contained in the metal films. Then, this causes metal silicide portions to form on the electrode layers WL and the select gates SG adjacent to the trenches 43s. Next, the remaining unreacted metal material is removed.

As illustrated in FIG. 6B, insulating layers 45a and 45b are formed in the trenches 43s. The insulating layer 45a is formed in the trench 43s in the stacked body 15, for example, and the insulating layer 45b is formed in the trench 43s above the stacked body 15. The insulating layer 45a serves as a protective film for the select gates SG.

The insulating layers 45a and 45b may be formed using the same material or different materials. The insulating layers 45a and 45b are silicon oxide films, for example. Accordingly, the insulating separators ST1 and ST2 are formed. The stopper layer 43 to be described below may then be formed in the insulating separators ST1 and ST2, for example.

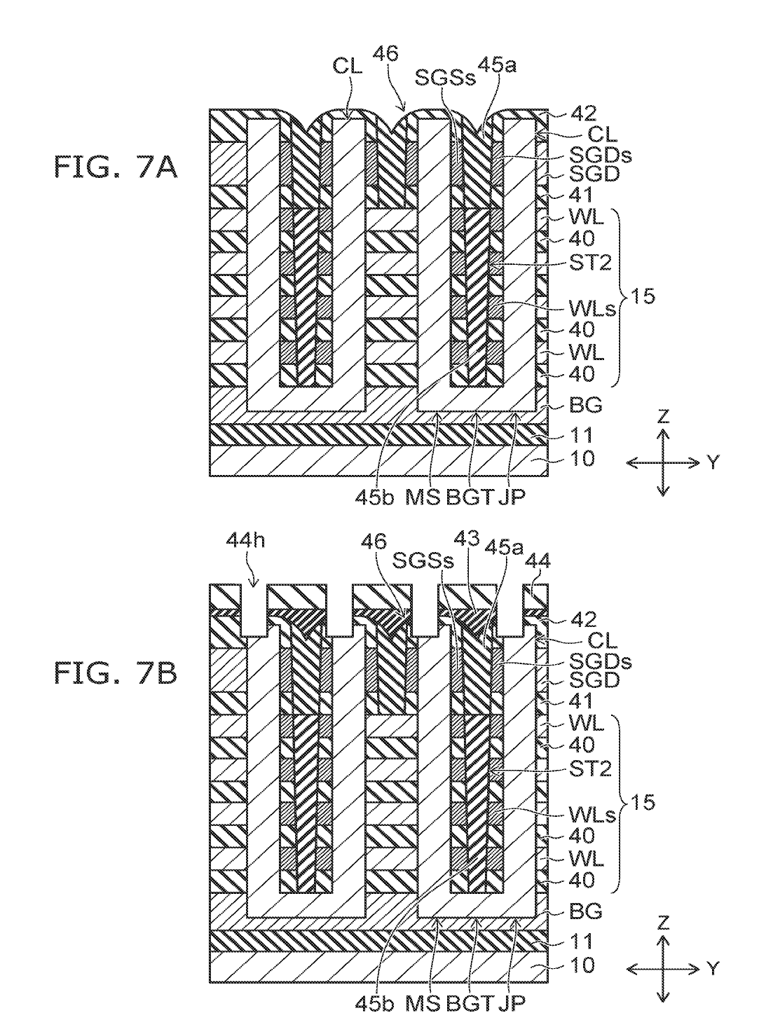

As illustrated in FIG. 7A, spaces 46 (recesses) are formed on the top ends of the insulating separators ST1. For forming the spaces 46, a method is used in which the corners of the insulating layers 45a are removed by RIE using a mask (not illustrated) or by a chemical process using diluted hydrofluoric acid, for example.

The spaces 46 are formed above the select gates SG. As viewed in the Z direction, the maximum diameter of the spaces 46 formed in the insulating separators ST1 is greater than the maximum diameter of the portions of the insulating separators ST1 below the spaces 46. The spaces 46 are formed overlapping with the select gates SG in the Z direction, for example.

The portions that will become the spaces 46 may also be formed by removing the insulating layer 42 by RIE before forming the insulating layers 45a and 45b, for example. In this case, the spaces 46 are formed by RIE.

As illustrated in FIG. 7B, a stopper layer 43 (an insulating layer) is formed in the spaces 46 of the insulating separators ST1 and on the insulating layer 42. The portions of the stopper layer 43 formed on the insulating separators ST1 are thicker than the portions formed on the select gates SG. Moreover, as viewed in the Z direction, the stopper layer 43 becomes thicker as the stopper layer 43 separates away from the column CL.

The stopper layer 43 includes a material different from a material of the insulating layer 42 and the insulating layer 45a. A silicon nitride film is used for the stopper layer 43, for example.

The stopper layer 43 is formed in the insulating layers 45a of the insulating separators ST1, for example. In this case, the stopper layer 43 is surrounded by the select gates SG with the insulating layers 45a disposed therebetween.

The stopper layer 43 includes cavities 43v, for example. The cavity 43v is surrounded by the select gates SG with the insulating layers 45a disposed therebetween. This makes it possible to reduce parasitic capacitance, reduce leakage current, or improve breakdown voltage in the insulating separators ST1.

Next, an insulating layer 44 is formed on the stopper layer 43. The insulating layer 44 includes at least one of a silicon oxide film and TEOS, for example.

Next, holes 44 h are formed going through the insulating layer 44 and the stopper layer 43 and reaching to the columns CL. The holes 44 h are formed by RIE using a mask (not illustrated), for example. The stopper layer 43 is used as an etching stopper layer while forming the holes 44h.

For example, if the stopper layer 43 is formed having a uniform thickness on the insulating layer 42, the holes 44 h are misaligned from the upper surfaces of the columns CL, the contact portions CN may be in contact with the stacked films (the select gates SG, the electrode layers WL, and the like), thereby causing a short-circuit.

If the upper surfaces of the columns CL are formed above the stacked films in order to avoid this type of contact, for example, the difficulty of the forming process and the filling process for the columns CL is increased.

In contrast, according to this embodiment, the stopper layer 43 is formed such that the thickness thereof becomes thicker as the stopper layer 43 separates away from the column CL. As a result, in the formation of the hole 44 h by etching through the bottom surface of the stopper layer 43 formed above the columns CL, the insulating layer 42 becomes exposed to a portion of the bottom surface of the hole 44 h while the stopper layer 43 becomes exposed to another portion of the bottom surface of the hole 44 h located further away from the column CL.

When, in this state, etching is performed on the insulating layer 42, the etching will proceed more slowly because the stopper layer 43 remains more as the stopper layer 43 separates away from the column CL. Therefore, when the holes 44 h that go through the bottom surface of the stopper layer 43 and reach the columns CL are formed, those holes 44 h are formed more shallowly as the holes 44 h separates away from the column CL.

As illustrated in FIG. 2A, the holes 44 h are filled with conductive films to form the contact portions CN. Next, the source layer SL, bit lines BL, and the like illustrated in FIG. 1 are formed on the insulating layer 44.

In this embodiment, the portion of the stopper layer 43 formed above the insulating separator ST1 are thicker than the portion formed above the select gate SG. Therefore, as illustrated in FIG. 3B, if the hole 44 h is formed misaligned from the upper surface of the column CL, the contact portion CN is formed more shallowly as the contact portion CN separates away from the column CL. This makes it possible to prevent the contact portions CN from being in contact with the stacked films and to reduce the difficulty associated with manufacturing three-dimensional devices on increasingly smaller scales.

Furthermore, the stopper layer 43 may be formed thicker as the stopper layer 43 separates away from the column CL. Therefore, the locations at which the spaces 46 are formed are optional.

Next, an example of a layout for this embodiment will be described with reference to FIG. 8B.

As illustrated in FIG. 8B, the spaces 46 are formed between the plurality of columns CL in the X direction and do not extend in the X and Y directions to the positions at which the columns CL are formed, for example. In other words, the spaces 46 are formed at positions separated from the columns CL.

Spaces 47 (third spaces) are formed on the insulating layer 42 formed between adjacent spaces 46 (first spaces and second spaces) in the Y direction. The spaces 47 may be formed between adjacent spaces 46 in the X direction, for example.

As a result, the spaces 47 are formed in the insulating layer 42 at positions separated from the columns CL in addition to the spaces 46 formed in the insulating separators ST1. Therefore, the portion of the stopper layer 43 formed on the spaces 47 is thicker than the portion of the stopper layer 43 formed on the insulating layer 42 at positions other than where the spaces 47 are located. This makes it possible to suppress the occurrence of errors in the alignment of the contact portions CN relative to the columns CL when forming those contact portions CN. In other words, this makes it possible to reduce the difficulty associated with manufacturing three-dimensional devices on increasingly smaller scales.

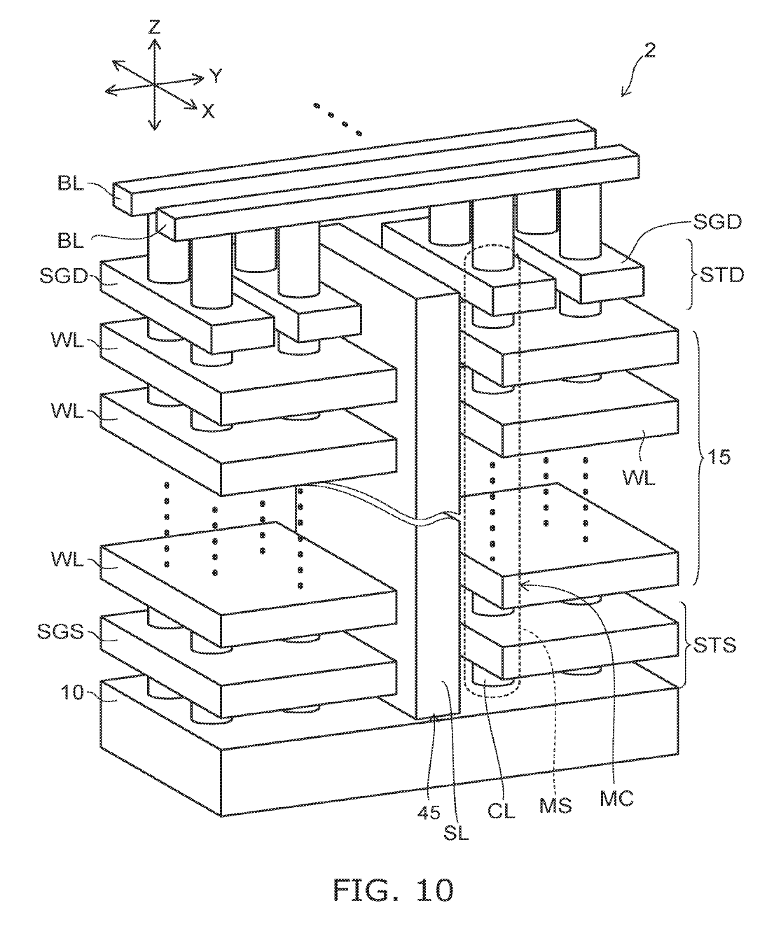

FIG. 10 is a perspective view schematically illustrating another example of a memory cell array 2 according to an embodiment of the semiconductor memory device. As in FIG. 1, for simplicity, elements such as the insulating layer are not illustrated in FIG. 10.

FIG. 10 includes a coordinate system in which two mutually orthogonal directions are the X direction and the Y direction, both of which run parallel to the primary plane of a substrate 10. Moreover, the Z direction (the stacking direction) is orthogonal to both the X and Y directions.

A source side select gate SGS (lower layer gate) is provided on the substrate 10 with an insulating layer disposed therebetween. A stacked body 15 is provided on the source side select gate SGS. The stacked body 15 includes a plurality of electrode layers WL, the plurality of electrode layers are separately stacked each other and a plurality of insulating layers 40 provided between the plurality of electrode layers WL. The electrode layers WL and insulating layers 40 are stacked alternately, for example.

A drain side select gate SGD (an upper layer gate) is provided on the stacked body 15. The above-described column CL is provided in the stacked body 15, the column CL extends in the Z direction through the stacked body 15. The column CL pierces the drain side select gate SGD, the plurality of electrode layers WL, and the source side select gate SGS and reaches the substrate 10. The top end of channel body 20 of the column CL is connected to a bit line BL, and the bottom end of the channel body 20 is electrically connected to a source layer SL via the substrate 10.

As in the embodiment described above, in the memory cell array 2 illustrated in FIG. 10, the stopper layer 43 is provided such that the thickness thereof becomes thicker as the stopper layer 43 separates away from the column CL. This makes it possible to suppress the occurrence of errors in the alignment of the contact portions CN relative to the columns CL when forming those contact portions CN. In other words, this makes it possible to reduce the difficulty associated with manufacturing three-dimensional devices on increasingly smaller scales.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

What is claimed is:

1. A semiconductor memory device comprising:
a stacked body including a plurality of electrode layers separately stacked each other;
a select gate provided on the stacked body;
a first insulating layer provided on the select gate;
a semiconductor portion provided in the stacked body and the select gate, the semiconductor portion extending in a stacking direction of the stacked body, the semiconductor portion including a top end portion positioned on the select gate;
a charge storage film provided between the semiconductor portion and the plurality of electrode layers;
a second insulating layer provided on the stacked body and extending in the stacking direction and in a first direction crossing the stacking direction, the second insulating layer being in contact with a side surface of the select gate and a side surface of the first insulating layer;
a third insulating layer continuously provided on the second insulating layer and the select gate, the third insulating layer including:
a first portion provided on the select gate with the first insulating layer between the first portion and the select gate, the first portion being in contact with an upper surface of the first insulating layer and separated from the second insulating layer, and
a second portion provided on the second insulating layer, the second portion being in contact with the second insulating layer and separated from the first insulating layer, a thickness of the second portion being thicker than a thickness of the first portion in the stacking direction; and
a contact portion connected to the top end portion of the semiconductor portion, the contact portion extending in the stacking direction.

2. The device according to claim 1, wherein
the third insulating layer includes a material different from a material included the second insulating layer.

3. The device according to claim 1, wherein
the third insulating layer includes a third portion provided between the first portion and the second portion, the third portion being in contact with at least one of the first insulating layer and the second insulating layer, a thickness of the third portion being thicker than the thickness of the first portion and thinner than the thickness of the second portion.

4. The device according to claim 3, wherein
as viewed in the stacking direction, the third portion overlaps with the select gate.

5. The device according to claim 1, wherein
the contact portion is provided more shallowly as the contact portion separates away from the semiconductor portion in a second direction crossing the stacking direction and the first direction.

6. The device according to claim 1, wherein
a thickness of the third insulating layer in the stacking direction becomes thicker as the third insulating layer separates away from the semiconductor portion in a second direction crossing the stacking direction and the first direction.

7. The device according to claim 1, wherein
the third insulating layer is provided in the second insulating layer.

8. The device according to claim 7, wherein
a cavity is provided in the third insulating layer provided in the second insulating layer.

9. The device according to claim 1, wherein
the third insulating layer is in contact with a side surface of the contact portion.

10. The device according to claim 1, wherein
the third insulating layer is a silicon nitride film, and
the second insulating layer is a silicon oxide film.

11. The device according to claim 1, wherein
the second insulating layer includes:
a first insulating film, and
a second insulating film separated from the first insulating film in a second direction crossing the stacking direction and the first direction with the semiconductor portion between the first insulating film and second insulating film, and
the third insulating layer includes a fourth portion provided between the first insulating film and the second insulating film, a thickness of the fourth portion being thicker than the thickness of the first portion and being thinner than the thickness of the second portion.

12. A method for manufacturing a semiconductor memory device, comprising:
forming a stacked body including a plurality of electrode layers separately stacked each other;
forming a select gate on the stacked body;
forming a hole piercing the select gate and the stacked body in a stacking direction of the stacked body;
forming a film including a charge storage film on an inner wall of the hole;
forming a semiconductor portion on an inner side of the film including the charge storage film;
forming a first insulating layer on the select gate and the semiconductor portion;
forming a trench piercing the select gate and the first insulating layer, the trench extending in a first direction crossing the stacking direction;
forming a second insulating layer in the trench;
forming a space in a top end of the second insulating layer;
forming a third insulating layer continuously in the space, on the select gate with the first insulating layer between the third insulating layer and the select gate and on the semiconductor portion with the first insulating layer between the third insulating layer and the semiconductor portion; and
forming a contact portion piercing the third insulating layer in the stacking direction and reaching the semiconductor portion.

13. The method according to claim 12, wherein
the forming the third insulating layer includes forming the third insulating layer in the space having a thickness being thicker than a thickness of the third insulating layer on the select gate in the stacking direction.

14. The method according to claim 12, wherein
the forming the third insulating layer includes forming the third insulating layer in the second insulating layer.

15. The method according to claim 14, wherein
the forming the third insulating layer includes leaving a cavity in the third insulating layer formed in the second insulating layer.

16. The method according to claim 12, wherein
the forming the contact portion includes forming the contact portion more shallowly as the contact portion separates away from the semiconductor portion in a second direction crossing the stacking direction and the first direction.

17. The method according to claim 12, wherein
the forming the third insulating layer includes making the third insulating layer thicker as the third insulating layer separates away from the semiconductor portion in a second direction crossing the stacking direction and the first direction.

18. The method according to claim 12, wherein
the third insulating layer including a material different from a material included the second insulating layer.

19. The method according to claim 12, wherein
the third insulating layer is a silicon nitride film, and
the second insulating layer is a silicon oxide film.

20. The method according to claim 12, wherein
the forming the space includes:
forming a first space and a second space in the top end of the second insulating layer; and
forming a third space between the first space and second space.
